(19) United States
(12) Patent Application Publication
(10) Pub. No.: US 2026/0017508 A1
(43) Pub. Date: Jan. 15, 2026

(54) BIPOLAR OPTICAL SYNAPTIC DEVICE

(71) Applicant: GIST(Gwangju Institute of Science and Technology), Gwangju (KR)

(72) Inventors: Dong Ho KANG, Gwangju (KR); Hye Jin YOON, Gwangju (KR); So Eun PARK, Gwangju (KR)

(73) Assignee: GIST(Gwangju Institute of Science and Technology), Gwangju (KR)

(21) Appl. No.: 19/237,694

(22) Filed: Jun. 13, 2025

(30) Foreign Application Priority Data
Jul. 14, 2024 (KR) 10-2024-0077416

(51) Int. Cl. G06N 3/067; H10D 30/69

(52) U.S. Cl. CPC G06N 3/0675; H10D 30/701

(57) ABSTRACT

The present disclosure relates to a bipolar optical synaptic device, and more specifically, to a bipolar optical synaptic device capable of operating solely by a light signal.

### CROSS REFERENCE TO RELATED APPLICATION

The present application claims priority to Korean Patent Application No. 10-2024-0077416, filed Jul. 14, 2024, the entire contents of which are incorporated herein for all purposes by this reference.

### BACKGROUND

### Technical Field

The present disclosure relates to a bipolar optical synaptic device, and more specifically, to a bipolar optical synaptic device capable of operating solely by a light signal.

### Description of the Related Art

To meet the rapidly increasing data processing demands, neuromorphic computing hardware technology that mimics the human brain neural network is receiving significant attention. Neuromorphic computing hardware can be largely divided into a neuron circuit and a synaptic device. Synaptic devices play a role in learning the importance of each input signal and determining weights, and they can readjust the weights through positive/negative feedback.

However, the previously developed synaptic devices are unipolar devices that can only have positive weight values, so two synaptic devices and a circuit (subtractor) capable of comparing their weight values are essential to implement positive/negative weights in hardware.

Further, when implementing neuromorphic computing hardware, in order to enable fast analysis and response close to real-time by processing, analyzing, and storing data at a sensor unit that collects data, the development of synaptic devices capable of operating by input signals of other types such as optical, thermal, and piezoelectric signals is necessary.

### PRIOR ART DOCUMENT

### Patent Document

Korean Patent Application Publication No. 10-2024-0066801

### SUMMARY

An objective of the present disclosure is to provide a bipolar optical synaptic device capable of operating with light while having both positive and negative weights.

Further, the objectives to implement in the present disclosure are not limited to the technical problems described above and other objects that are not stated herein will be clearly understood by those skilled in the art from the following specifications.

In order to achieve the objectives, a bipolar optical synaptic device according to an embodiment of the present disclosure includes: a lower electrode; a weight control layer formed on the lower electrode and receiving a bias voltage; a semiconductor channel layer formed on the weight control layer and in which the sign of the Fermi level is controlled in accordance with the bias voltage; and at least one or more upper electrodes formed on the semiconductor channel layer.

The weight control layer may include an insulating material and a ferroelectric material.

The insulating material a trap layer capable of capturing charges while having a bandgap greater than 2 eV.

The ferroelectric material may control electric polarization in a material by an electric or magnetic field.

The semiconductor channel layer may be made of a material that can control the Fermi level by the weight control layer.

The upper electrode may be composed of a first upper electrode and a second upper electrode, and the first upper electrode and the second upper electrode may be formed spaced apart from each other on the semiconductor channel layer.

The semiconductor channel layer may include a first semiconductor channel layer and a second semiconductor channel layer.

The first semiconductor channel layer may be made of a material that is relatively less influenced by Fermi level pinning than the second semiconductor channel layer.

The first upper electrode may be formed on the first semiconductor channel layer, and the second upper electrode may be formed on the second semiconductor channel layer.

The first semiconductor channel layer and the second semiconductor channel layer may be horizontally arranged on the same plane.

The first semiconductor channel layer and the second semiconductor channel layer may be stacked and vertically arranged.

The second semiconductor channel layer may be formed on the first semiconductor channel layer.

According to the present disclosure described above, since it is possible to operate a device by using only the photovoltaic effect caused by a light signal without applying a device operation voltage, there is an effect of achieving very low power consumption.

Further, by placing a material that is relatively less influenced by the Fermi level pinning phenomenon on a weight control layer, it is possible to derive both positive and negative bipolar current values of a device according to the weight control, thereby achieving an effect of significantly improving energy efficiency compared to a weight circuit including two synaptic devices of the related art.

### BRIEF DESCRIPTION OF THE DRAWINGS

FIG. 1 illustrates a structural diagram of a bipolar synaptic device according to an example of the optical present disclosure;

FIG. 2 illustrates a fabrication process of the bipolar optical synaptic device of FIG. 1;

FIG. 3 illustrates a structural diagram of a bipolar optical synaptic device according to another example of the present disclosure;

FIG. 4 illustrates a fabrication process of the bipolar optical synaptic device of FIG. 3;

FIG. 5 illustrates a structural diagram of a bipolar optical synaptic device according to another example of the present disclosure;

FIG. 6 illustrates a fabrication process of the bipolar optical synaptic device of FIG. 5;

FIG. 7 illustrates a structural diagram of a bipolar optical synaptic device according to another example of the present disclosure;

FIG. 8 illustrates a fabrication process of the bipolar optical synaptic device of FIG. 7;

FIG. 9 and FIG. 10 illustrate a weight mechanism of a bipolar optical synaptic device when positive and negative currents are applied;

FIG. 11 illustrates voltage and current variations of a bipolar optical synaptic device according to positive and negative weights; and

FIG. 12 illustrates conductance of a bipolar optical synaptic device over time.

### DETAILED DESCRIPTION

Hereafter, embodiments of the present disclosure will be described in detail so that those skilled in the art can easily achieve the present disclosure. However, the present disclosure may be modified in various different ways and is not limited to the embodiments described herein.

A bipolar optical synaptic device 10 according to an embodiment of the present disclosure includes a lower electrode 110, a weight control layer 120, a semiconductor channel layer 130, and an upper electrode 140.

The lower electrode 110, which is a weight control electrode, may be an element that receives a weight control signal in the form of a gate pulse and controls the intensity of current using a field effect generated. The lower electrode 110 may include at least one or more of gold (Au), platinum (Pt), titanium (Ti), chromium (Cr), palladium (Pd), and copper (Cu).

The weight control layer 120 may be capable of storing a weight control amount in response to application of a weight control signal from the lower electrode 110, and the weight control amount may be a charge amount or electric polarization. Accordingly, the weight control layer 120 may include an insulating material and a ferroelectric material capable of storing a weight control amount.

The insulating material may store a weight control amount, and more specifically, may store a charge amount and electric polarization. The insulating material may include a trap layer capable of capturing charges while having a bandgap greater than 2 eV, and the insulating material, which is a material for forming an oxide film, may be one or two or more materials selected from a group of nitrogen oxide (NOx), boron oxide ((BO)x), SiO₂, Al₂O₃, HfO₂, ZrO₂, and Ta₂O₅.

The ferroelectric material may control electric polarization in a material by an electric or magnetic field, and the ferroelectric material may be P (VDF-TrFE), CIPS (CuInP₂S₆), or In₂Se₃.

The semiconductor channel layer 130 may control the Fermi level depending on the bias voltage applied to the weight control layer 120. More specifically, on the basis of the weight control amount stored in the weight control layer 130, the direction of a built-in field formed in the channel may be determined depending on the position of the Fermi level in the semiconductor channel layer, and accordingly, it may have a positive or negative current value.

The semiconductor channel layer 130 may be a material in which the Fermi level can be controlled by the amount of charges stored in the weight control layer 120, and more specifically, the semiconductor channel layer 130 may be one or more materials selected from a group of Si, Ge, MoS₂, WSe₂, ReS₂, and ReSe₂.

The semiconductor channel layer 130 may be composed of a first semiconductor channel layer 131 and a second semiconductor channel layer 132, and the first semiconductor channel layer 131 and the second semiconductor channel layer 132 may be distinguished on the basis of different degrees of influence by Fermi level pinning. More specifically, at least any one of the first semiconductor channel layer 131 and the second semiconductor channel layer 132 may be made of a material that is relatively less influenced by Fermi level pinning than the other. For example, when the first semiconductor channel layer 131 is made of a material that is relatively less influenced by Fermi level pinning than the second semiconductor channel layer 132, the first semiconductor channel layer 131 may include WSe₂ and/or ReSe₂, and the second semiconductor channel layer 132 may include MoS₂ and/or ReS₂.

The upper electrode 140 may be capable of reading the current value of the semiconductor channel layer 130. The upper electrode 140 may be composed of a first upper electrode 141 and a second upper electrode 142. The first upper electrode 141 and the second upper electrode 142 may be source electrodes or drain electrodes, and the first upper electrode 141 and the second upper electrode 142 may each include any one or more of gold (Au), platinum (Pt), titanium (Ti), chromium (Cr), palladium (Pd), and copper (Cu).

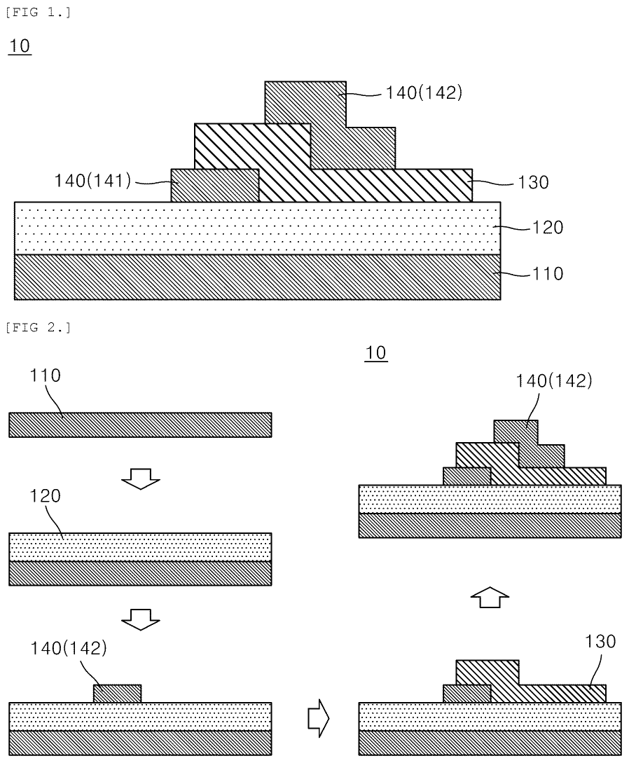

FIG. 1 illustrates a structural diagram of a bipolar optical synaptic device 10 according to an example of the present disclosure. referring to FIG. 1, the bipolar optical synaptic device 10 includes: a lower electrode 110; a weight control layer 120 formed on the lower electrode 110 and to which a bias voltage is applied; a semiconductor channel layer 130 formed on the weight control layer 120 and in which the sign of the Fermi level is controlled in accordance with the bias voltage; and at least one or more upper electrodes 140 formed on the semiconductor channel layer.

Referring to FIG. 1, the upper electrode 140 is composed of a first upper electrode 141 and a second upper electrode 142, the first upper electrode 141 may be formed on the weight control layer 120, and the second upper electrode 142 may be formed on the semiconductor channel layer 130. In this configuration, the first upper electrode 141 may be a side electrode in relation to the semiconductor channel layer 130, and a part of the semiconductor channel layer 130 may be in contact with the first upper electrode 141.

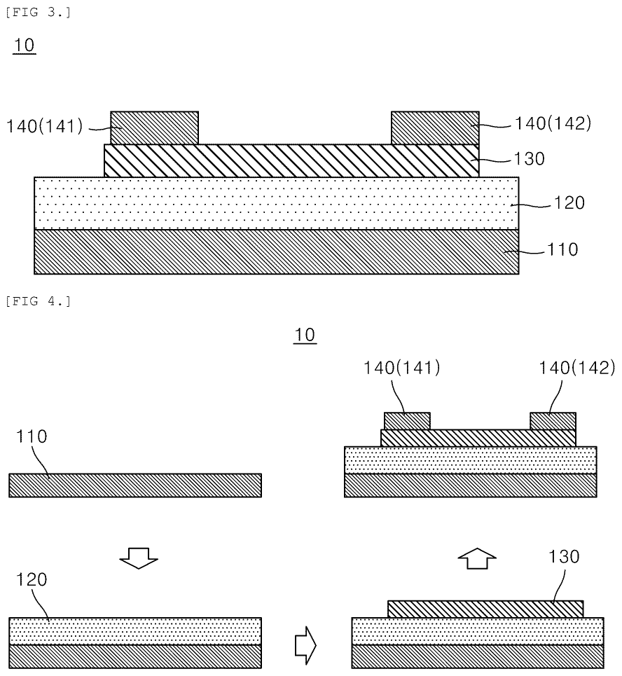

The bipolar optical synaptic device 10 according to FIG. 1 may be fabricated in the order according to FIG. 2. Referring to FIG. 2, the lower electrode 110 is provided, and the weight control layer 120 is formed on the lower electrode 110. Thereafter, the first upper electrode 141 is formed on the weight control layer 120, the semiconductor channel layer 130 is formed on the weight control layer 120 to be in contact with the first upper electrode 141, and finally, the second upper electrode 142 is formed on the semiconductor channel layer 130, thereby fabricating the bipolar optical synaptic device 10.

FIG. 3 illustrates a structural diagram of a bipolar optical synaptic device 10 according to another example of the present disclosure. Referring to FIG. 3, a first upper electrode 141 and a second upper electrode 142 may be formed on a semiconductor channel layer 130, as an upper electrode 140, and the first upper electrode 141 and the second upper electrode 142 may be formed spaced apart from each other on the same plane on the semiconductor channel layer 130.

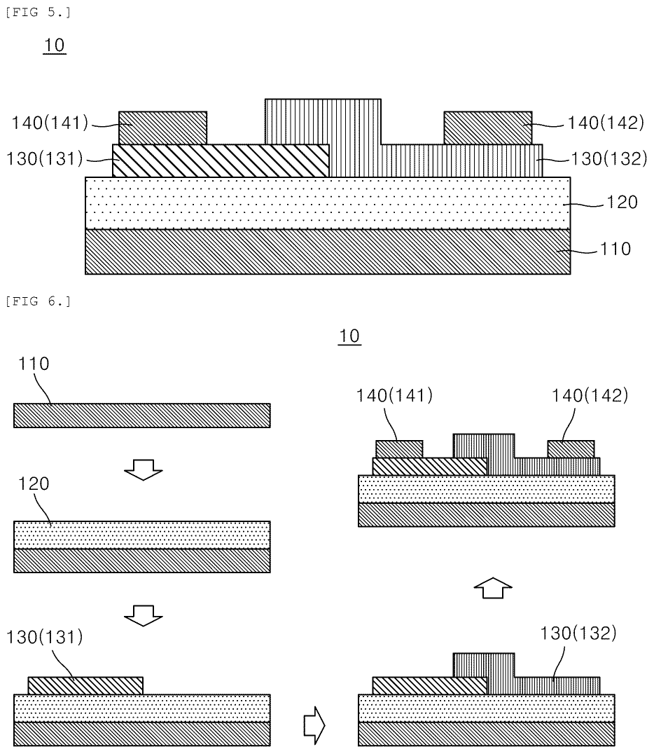

The bipolar optical synaptic device 10 according to FIG. 3 may be fabricated in the order according to FIG. 4. Referring to FIG. 4, a lower electrode 110 is provided, and a weight control layer 120 is formed on the lower electrode 110. Thereafter, the semiconductor channel layer 130 is formed on the weight control layer 120, and finally, the first upper electrode 141 and the second upper electrode 142 are formed spaced apart from each other on the semiconductor channel layer 130, thereby fabricating the bipolar optical synaptic device 10.

FIG. 5 illustrates a structural diagram of a bipolar optical synaptic device 10 according to another example of the present disclosure. Referring to FIG. 5, a semiconductor channel layer 130 may be composed of a first semiconductor channel layer 131 and a second semiconductor channel layer 132, the first semiconductor channel layer 131 and the second semiconductor channel layer 132 may be formed on the same plane on the weight control layer 120, and accordingly, the first semiconductor channel layer 131 and the second semiconductor channel layer 132 may form a horizontal structure. In this configuration, as an upper electrode 140, a first upper electrode 141 may be formed on the first semiconductor channel layer 131, and a second upper electrode 142 may be formed on the second semiconductor channel layer 132.

The bipolar optical synaptic device 10 according to FIG. 5 may be fabricated in the order according to FIG. 6. Referring to FIG. 6, a lower electrode 110 is provided, and a weight control layer 120 is formed on the lower electrode 110. Thereafter, the first semiconductor channel layer 131 is formed on the weight control layer 120, and the second semiconductor channel layer 132 is formed on the same plane as the first semiconductor channel layer 131 on the weight control layer 120. Finally, the first upper electrode 141 is formed on the first semiconductor channel layer 131, and the second upper electrode 142 is formed on the second semiconductor channel layer 132, thereby fabricating the bipolar optical synaptic device 10.

FIG. 7 illustrates a structural diagram of a bipolar optical synaptic device 10 according to another example of the present disclosure. Referring to FIG. 7, in a semiconductor channel layer 130, a first semiconductor channel layer 131 may be formed on a weight control layer 120, and a second semiconductor channel layer 132 may be formed on the first semiconductor channel layer 131, and accordingly, the first semiconductor channel layer 131 and the second semiconductor channel layer 132 may form a vertical structure. Further, the first semiconductor channel layer 131 may be made of a material that is relatively less influenced by Fermi pinning level than the second semiconductor channel layer 132, the first semiconductor channel layer 131 may include WSe₂ and/or ReSe₂, and the second semiconductor channel layer 132 may include MoS₂ and/or ReS₂. In this configuration, as an upper electrode 140, a first upper electrode 141 may be formed on the first semiconductor channel layer 131, and a second upper electrode 142 may be formed on the second semiconductor channel layer 132.

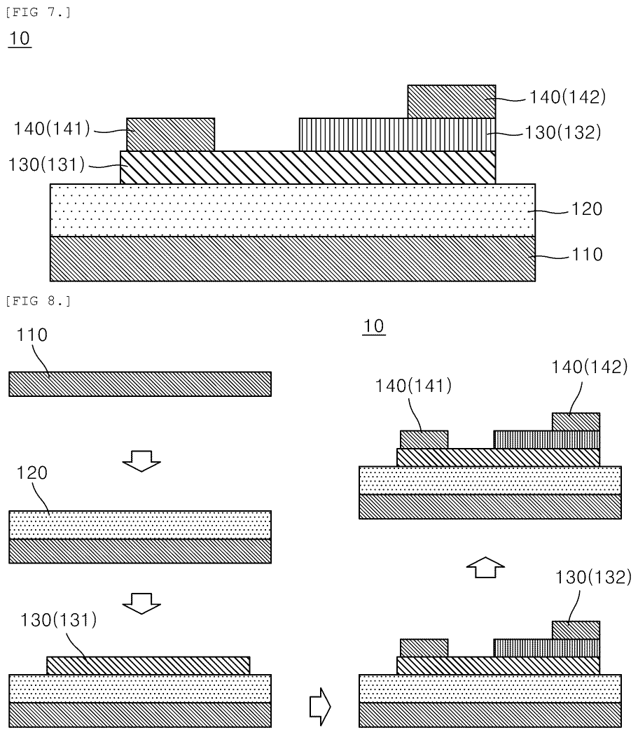

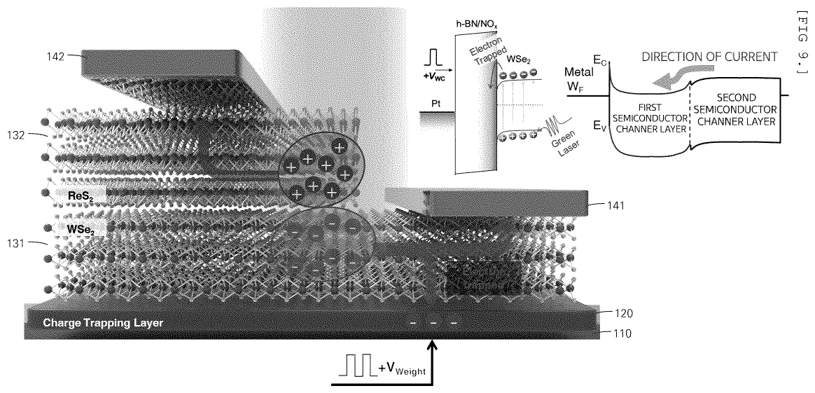

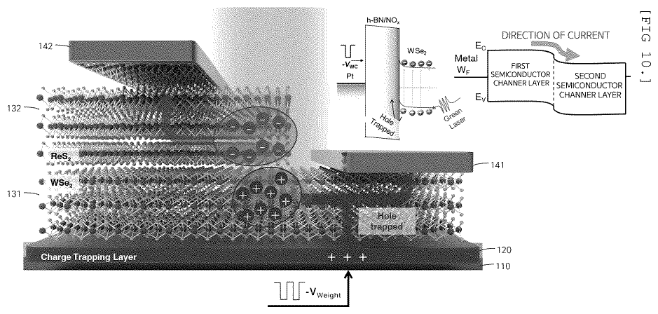

The bipolar optical synaptic device 10 according to FIG. 7 may be fabricated in the order according to FIG. 8. Referring to FIG. 8, a lower electrode 110 is provided, and a weight control layer 120 is formed on the lower electrode 110. Thereafter, the first semiconductor channel layer 131 is formed on the weight control layer 120, and the second semiconductor channel layer 132 is formed on the first semiconductor channel layer 131, thereby forming a vertical structure. Finally, the first upper electrode 141 is formed on the first semiconductor channel layer 131, and the second upper electrode 142 is formed on the second semiconductor channel layer 132, thereby fabricating the bipolar optical synaptic device 10.

Hereafter, the present disclosure is described in more detail through embodiments. The following embodiment is only an example for helping understand the present disclosure without limiting the present disclosure. Further, through the following embodiment, the technical features of the present disclosure may be more easily understood, and the scope of rights extends to inventions including the technical features of the present disclosure.

### Embodiment. Fabrication of Bipolar Optical Synaptic Device

A bipolar optical synaptic device 10 having the structure shown in FIG. 7 was fabricated, in which a lower electrode 110, a first upper electrode 141, and a second upper electrode 142 were all made of platinum Pt. As a weight control layer 120, an oxide layer (NOx and (BO)x) was formed by performing O₂ plasma treatment (470 mTorr, O₂ flow rate: 5 sccm) on hexagonal boron nitride (h-BN). Further, as a semiconductor channel layer 130, a first semiconductor channel layer 131 was made of ReS₂ and a second semiconductor channel layer 132 was made of WSe₂.

### Experimental Example

When a positive current (positive weight) and a negative current (negative weight) were applied to the bipolar optical synaptic device 10 fabricated in the above embodiment, the operating mechanism of the bipolar optical synaptic device 10 was illustrated in FIG. 9 and FIG. 10.

Referring to FIG. 9, when, first, a light signal is emitted onto the first semiconductor channel layer 131 and the second semiconductor channel layer 132, electron-hole pairs are generated inside the channels, and a photovoltaic effect occurs due to the internal electric field within the channels, whereby a current flowing between the first upper electrode 141 and the second upper electrode 142 is generated. Subsequently, when a positive voltage pulse (positive weight) is applied to the lower electrode 110 of the bipolar optical synaptic device 10, electrons flowing in the first semiconductor channel layer 131 are trapped, and some of the electrons of the first semiconductor channel layer 131 and the second semiconductor channel layer 132 are stored in the weight control layer 120, while the remaining electrons move to the first upper electrode 141. At the same time, holes are formed in the first semiconductor channel layer 131 and the second semiconductor channel layer 132, and the holes move to the second upper electrode 142.

Referring to FIG. 10, when a light signal is emitted onto the first semiconductor channel layer 131 and the second semiconductor channel layer 132, electron-hole pairs are generated inside the channels, and a photovoltaic effect occurs due to the internal electric field within the channels, whereby a current flowing between the first upper electrode 141 and the second upper electrode 142 is generated. Subsequently, when a negative voltage pulse (negative weight) is applied to the lower electrode 110 of the bipolar optical synaptic device 10, holes are trapped in the first semiconductor channel layer 131, and some of the holes of the first semiconductor channel layer 131 are stored in the weight control layer 120, while the remaining holes move to the first upper electrode 141. At the same time, electrons are generated in the first semiconductor channel layer 131 and the second semiconductor channel layer 132, and the electrons move to the second upper electrode 142.

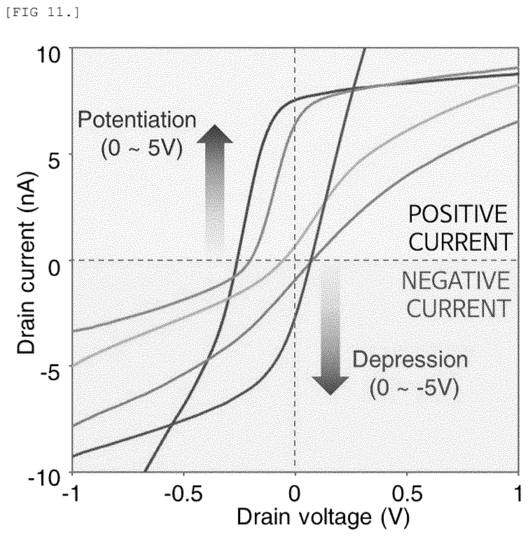

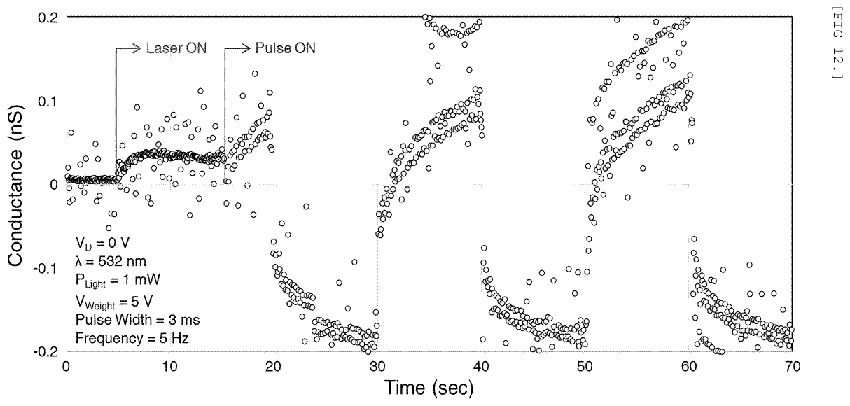

With respect to the bipolar optical synaptic device 10 fabricated in the above embodiment, when positive and negative voltages are applied to the lower electrode, the positive current and negative current flowing through the first semiconductor channel layer 131 and the second semiconductor channel layer 132 were measured in accordance with voltage (drain voltage) and current (drain current), and the results are shown in FIG. 11. Referring to FIG. 11, when a positive voltage of 0 to 5 V is applied to the lower electrode 110, a positive current flows, and in particular, potentiation in which as the intensity of the voltage increases, the positive current value increases in the positive direction was observed. This means that the higher the positive voltage applied to the lower electrode 110, the more positive current flows. On the other hand, when a negative voltage of 0 to-5 V is applied to the lower electrode 110, a negative current flows, and in particular, depression in which as the intensity of the voltage increases, the negative current value increases in the negative direction was observed. This means that the higher the negative voltage applied to the lower electrode 110, the more negative current flows.

Conductance of the bipolar optical synapse device 10 fabricated in the above embodiment was measured over time, and the measurement results are shown in FIG. 12. When a laser signal was emitted without applying an operating voltage (drain voltage), it was observed that a current flowed between the first upper electrode 141 and the second upper electrode 142 due to the photovoltaic effect. Thereafter, positive and negative gate pulses were repeatedly applied to the lower electrode 110. When the conductance value of the bipolar optical synaptic device 10 was measured over time, the conductance value sequentially increased from negative to positive when the positive gate pulse was applied, which successfully simulated long-term potentiation (LTP), one of synaptic plasticity. On the other hand, when the negative gate pulse was applied, the conductance value sequentially decreased from positive to negative, which successfully simulated long-term depression (LTD), one of synaptic plasticity.

Although embodiments of the present disclosure were described above in detail, the spirit of the present disclosure is not limited thereto and the present disclosure may be changed and modified in various ways on the basis of the basic concept without departing from the scope of the present disclosure described in the following claims.

What is claimed is:

1. A bipolar optical synaptic device comprising:
a lower electrode;
a weight control layer formed on the lower electrode and receiving a bias voltage;
a semiconductor channel layer formed on the weight control layer and in which the sign of the Fermi level is controlled in accordance with the bias voltage; and
at least one or more upper electrodes formed on the semiconductor channel layer.

2. The bipolar optical synaptic device of claim 1, wherein the weight control layer includes an insulating material and a ferroelectric material.

3. The bipolar optical synaptic device of claim 2, wherein the insulating material includes a trap layer capable of capturing charges while having a bandgap greater than 2 eV.

4. The bipolar optical synaptic device of claim 2, wherein the ferroelectric material can control electric polarization in a material by an electric or magnetic field.

5. The bipolar optical synaptic device of claim 1, wherein the semiconductor channel layer is made of a material that can control the Fermi level by the weight control layer.

6. The bipolar optical synaptic device of claim 1, wherein the upper electrode is composed of a first upper electrode and a second upper electrode, and
the first upper electrode and the second upper electrode are formed spaced apart from each other on the semiconductor channel layer.

7. The bipolar optical synaptic device of claim 1, wherein the semiconductor channel layer includes a first semiconductor channel layer and a second semiconductor channel layer.

8. The bipolar optical synaptic device of claim 7, wherein the first semiconductor channel layer is made of a material that is relatively less influenced by Fermi level pinning than the second semiconductor channel layer.

9. The bipolar optical synaptic device of claim 7, wherein the first upper electrode is formed on the first semiconductor channel layer, and
the second upper electrode is formed on the second semiconductor channel layer.

10. The bipolar optical synaptic device of claim 9, wherein the first semiconductor channel layer and the second semiconductor channel layer are horizontally arranged on the same plane.

11. The bipolar optical synaptic device of claim 9, wherein the first semiconductor channel layer and the second semiconductor channel layer are stacked and vertically arranged.

12. The bipolar optical synaptic device of claim 10, wherein the second semiconductor channel layer is formed on the first semiconductor channel layer.
